(19) United States
(12) Patent Application Publication
(10) Pub. No.: US 2019/0229296 A1
(43) Pub. Date: Jul. 25, 2019

(54) SUBSTRATE AND METHOD FOR FABRICATING ORGANIC LIGHT-EMITTING DIODES

(71) Applicant: Wuhan China Star Optoelectronics Semiconductor Display Technology Co., Ltd., Wuhan, Hubei (CN)

(72) Inventor: Shimin CHEN, Wuhan, Hubei (CN)

(21) Appl. No.: 15/578,133

(22) PCT Filed: Nov. 14, 2017
(86) PCT No.: PCT/CN2017/110906

§ 371 Date: Nov. 29, 2017

(30) Foreign Application Priority Data
Oct. 26, 2017 (CN) 201711025367.9

(51) Int. Cl. H01L 51/56; H01L 27/32; H01L 51/50; H01L 51/52

(52) U.S. Cl. CPC H01L 51/56; H01L 51/5203; H01L 51/5012; H01L 27/32

(57) ABSTRACT

The present disclosure discloses a substrate and a method for fabricating organic light-emitting diodes. The substrate includes a first base layer, a binding layer, and a second base layer, and the binding layer is bound between the first base layer and the second base layer, and the binding layer includes an ultraviolet rays (UV) decomposition resin. A polyimide film is formed in the substrate and bound to the bottom base layer through the UV decomposition resin. After forming organic light-emitting diodes, the bottom base layer is irradiated by ultraviolet rays and then easily peeled off without an additional back plate that performs a supporting function. Thus, the cost of peeling off the substrate is greatly reduced and the fabrication yield is improved.

### RELATED APPLICATIONS

The present application is a National Phase of International Application Number PCT/CN2017/110906, filed Nov. 14, 2017, and claims the priority of China Application No. 201711025367.9, filed Oct. 26, 2017.

### BACKGROUND OF THE INVENTION

### 1. Field of the Invention

The present disclosure relates to an organic light-emitting diode technical field, particularly to a substrate and a method for fabricating organic light-emitting diodes.

### 2. The Related Arts

Owning to the advantages of organic light-emitting diodes (OLEDs), OLEDs are called dream displays by industrial persons. Besides, OLEDs are acknowledged as developing displays in the next generation. An OLED panel may become thinner since its pixels can emit light without an independent backlight source. More importantly. An OLED panel may be curved and flexible. The OLED mainly has solid flexible organic material with very thin thickness. OLEDs cooperate with a flexible substrate and a cover to fabricate an OLED flexible display that can be curved.

The flexible substrate includes plastic, a polyester film, or a prepreg. Since electrodes or thin-film transistors (different thin-film transistor array substrates are fabricated in different emitting ways) are sputtered on the flexible substrate, the flexible substrate is made of polymer that resists high temperature, where polyimide (PI) is frequently used.

The polyimide film of an OLED module is covered with a protective substrate. The protective substrate is a carrier plated with the PI film. When the flexible OLED module is transported, the protective substrate can protect the OLED module. However, in the process of fabricating a flexible OLED module, the technique of peeling off the protective substrate is very complicated. In general, the laser lift-off (LLO) technique is used to break the adhesion between the substrate and the PI film, and then the substrate is removed. Finally, a thinner back plate adheres to the PI film to support the module. In addition, the required LLO equipment has the high cost and low yield.

### SUMMARY

In order to overcome the abovementioned problem, the primary objective of the present disclosure is to provide a substrate and a method for fabricating organic light-emitting diodes, which greatly reduces the cost of peeling off the substrate and improves the fabrication yield.

To achieve the abovementioned objectives, the present disclosure proposes a substrate, which comprises a first base layer, a binding layer, and a second base layer, and the binding layer is bound between the first base layer and the second base layer, and the binding layer includes an ultraviolet rays (UV) decomposition resin.

In an embodiment of the present disclosure, the thickness of the first base layer is larger than that of the second base layer.

In an embodiment of the present disclosure, the first base layer includes glass and the second base layer includes polyethylene terephthalate.

The present disclosure also proposes a method for fabricating organic light-emitting diodes comprising: providing a substrate including a first base layer, a binding layer, and a second base layer, and the binding layer is bound between the first base layer and the second base layer, and the binding layer includes an ultraviolet rays (UV) decomposition resin; forming a polyimide (PI) film on the second base layer; sequentially forming a first electrode layer, a function layer, a second electrode layer, and a package layer, using ultraviolet rays to irradiate the first base layer of the substrate, thereby decomposing the binding layer and peeling off the first base layer to form organic light-emitting diodes.

In an embodiment of the present disclosure, the thickness of the first base layer is larger than that of the second base layer.

In an embodiment of the present disclosure, the first base layer includes glass and the second base layer includes polyethylene terephthalate.

In an embodiment of the present disclosure, the binding layer is doped with a photosensitive resin.

In an embodiment of the present disclosure, the binding layer includes an acrylate copolymer solution, a multi-functional group photosensitive resin, a photoinitiator, and a plasticizer.

In an embodiment of the present disclosure, the multi-functional group photosensitive resin is three-group polyurethane acrylate.

The present disclosure forms the PI film in the substrate and binds the first base layer to the second base layer through the UV decomposition resin. After forming organic light-emitting diodes, the bottom base layer is irradiated by ultraviolet rays and then easily peeled off without an additional back plate that performs a supporting function. Thus, the cost of peeling off the substrate is greatly reduced and the fabrication yield is improved.

### BRIEF DESCRIPTION OF THE DRAWINGS

Accompanying drawings are for providing further understanding of embodiments of the disclosure. The drawings form a part of the disclosure and are for illustrating the principle of the embodiments of the disclosure along with the literal description. Apparently, the drawings in the description below are merely some embodiments of the disclosure, a person skilled in the art can obtain other drawings according to these drawings without creative efforts. In the figures:

FIG. 1 is a diagram schematically showing a substrate according to one embodiment of the present disclosure;

FIG. 2 is a diagram schematically showing the process of fabricating organic light-emitting diodes according to one embodiment of the present disclosure; and

FIG. 3 is a flowchart of fabricating organic light-emitting diodes according to one embodiment of the present disclosure.

### DETAILED DESCRIPTION OF THE PREFERRED EMBODIMENTS

Reference will now be made in detail to embodiments illustrated in the accompanying drawings. Wherever possible, the same reference numbers are used in the drawings and the description to refer to the same or like parts. In the drawings, the shape and thickness may be exaggerated for clarity and convenience. This description will be directed in particular to elements forming part of, or cooperating more directly with, methods and apparatus in accordance with the present disclosure. It is to be understood that elements not specifically shown or described may take various forms well known to those skilled in the art. Many alternatives and modifications will be apparent to those skilled in the art, once informed by the present disclosure.

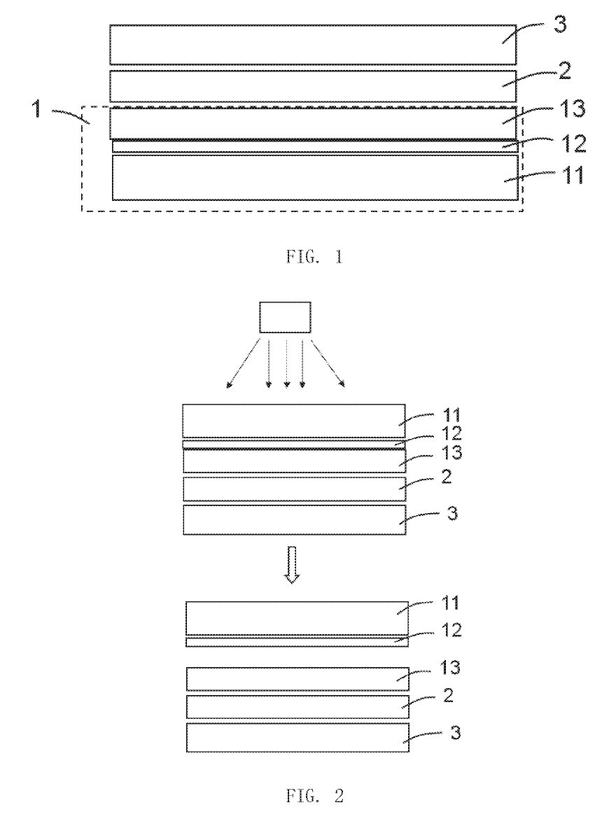

Refer to FIG. 1. According to an embodiment of the present disclosure, the substrate 1 comprises a first base layer 11, a binding layer 12, and a second base layer 13 disposed from bottom to top, and the binding layer 12 is bound between the first base layer 11 and the second base layer 13, and the binding layer 12 includes an ultraviolet rays (UV) decomposition resin. After fabricating the substrate 1, a polyimide (PI) layer 2 is coated on the upper surface of the second base layer 13. Then, organic light-emitting diodes (OLEDs) are formed on the PI layer 2.

The substrate 1 has two base layers. The first base layer 11 is used as an external protective layer. The first base layer 11 has supporting and protective functions when it is transported. Compared with the second base layer 13, the first base layer 11 is harder and thicker. The first base layer 11 includes glass and the second base layer 13 includes polyethylene terephthalate (PET). The second base layer 13 is made of PET that resists high temperature and corrosion and is suitably plated with the PI film and used as a supporting back plate to greatly reduce the thickness of the organic light-emitting diodes.

The first base layer 11 is bound to the second base layer 13 through the UV decomposition resin. The peeling technique of the first base layer 11 is simpler than the conventional laser lift-off (LLO) technique. The first base layer 11 is irradiated by ultraviolet rays such that the binding layer 12 separates from the second base layer 13. The second base layer 13 remains on the bottom of the PI film 2 to form a part of the OLEDs. In the embodiment, a polyimide solution coated on the upper surface of the second base layer 13 is solidified into the PI film 2, which is used as an underlay of a structural layer 3 of the OLEDs. The structural layer 3 includes, but not limited to, an electrode, a function layer, and a package layer. The electrode may be a metal electrode or a transparent electrode. The function layer includes, but not limited to, an organic light-emitting layer, a hole transporting layer, and an electron transporting layer. The hole transporting layer and the electron transporting layer are respectively formed at top and bottom sides of the organic light-emitting layer.

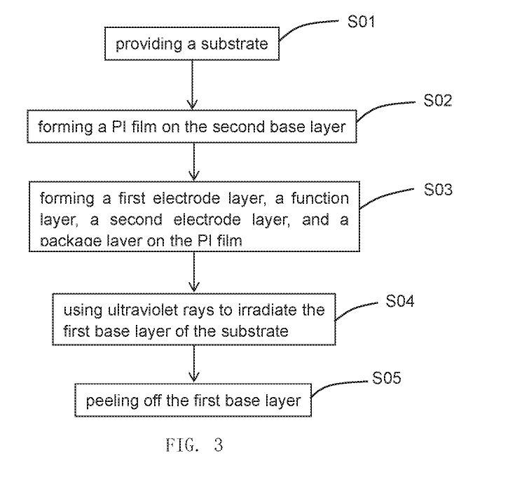

Refer to FIG. 2 and FIG. 3. The present disclosure provides a method for fabricating organic light-emitting diodes, which comprises:

Step S01: providing a substrate 1 including a first base layer 11, a binding layer 12, and a second base layer 13, and the binding layer 12 is bound between the first base layer 11 and the second base layer 13, and the binding layer 12 includes an ultraviolet rays (UV) decomposition resin;

Step S02: forming a polyimide (PI) film 2 on the second base layer 13;

Step S03: sequentially forming a first electrode layer, a function layer, a second electrode layer, and a package layer on the PI film 2;

Step S04: using ultraviolet rays to irradiate the first base layer 11 of the substrate, thereby decomposing the binding layer 12; and

Step S05: peeling off the first base layer 11 to form organic light-emitting diodes.

The first base layer 11 includes glass and the second base layer 13 includes polyethylene terephthalate (PET). The thickness of the first base layer 11 is larger than that of the second base layer 13. The PI film 2 is coated on the upper surface of the second base layer 13. Besides, in Step S02, the PI film 2 is provided with a package layer or other structures.

The binding layer 12 is doped with a photosensitive resin to guarantee the good adhesion-free effect for UV light. Specifically, the binding layer 12 includes an acrylate copolymer solution, a multi-functional group photosensitive resin, a photoinitiator, and a plasticizer. The acrylate copolymer solution mainly includes ethyl acrylate (EA), iso-octyl acrylate (2-EHA), methyl methacrylate (MMA), acrylic acid (AA). 2-EHA is used as viscous monomer that initially provides the viscousness of the colloid. MMA is used as cohesive monomer that adjusts the cohesive properties of the adhesive and copolymerizes soft monomer. AA is used as modified monomer that adds polar groups-carboxyl to macromolecular chains, such that hydrogen bonds are formed between the polymer molecular chains. Thus, the cohesive strength and viscous properties of the polymers are greatly improved.

The acrylate copolymer solution with reactive groups is prepared in a solution-polymerizing way and then mixed with the multi-functional group photosensitive resin to form the binding layer 12. In the embodiment, the multi-functional group photosensitive resin is three-group polyurethane acrylate. Adding too little photosensitive resin represents that the adhesion-free effect is not apparent. Adding too much photosensitive resin will make the colloid too soft. As a result, the performance of the entire product depends on the amount of the photosensitive resin. According to experiments, the product has the best comprehensive performance by adding 75%-100% weight percentage of three-group polyurethane acrylate in total weight of acrylate monomer, by adding 15% weight percentage of AA in total weight of acrylate monomer, or by adding 25% weight percentage of the plasticizer in total weight of acrylate monomer.

The present disclosure forms the PI film in the substrate and binds the first base layer to the second base layer through the UV decomposition resin. After forming organic light-emitting diodes, the bottom base layer is irradiated by ultraviolet rays and then easily peeled off without an additional back plate that performs a supporting function. Thus, the cost of peeling off the substrate is greatly reduced and the fabrication yield is improved.

The foregoing contents are detailed description of the disclosure in conjunction with specific preferred embodiments and concrete embodiments of the disclosure are not limited to these description. For the person skilled in the art of the disclosure, without departing from the concept of the disclosure, simple deductions or substitutions can be made and should be included in the protection scope of the application.

What is claimed is:

1. A substrate comprising a first base layer, a binding layer, and a second base layer, wherein the binding layer is bound between the first base layer and the second base layer, and the binding layer includes an ultraviolet rays (UV) decomposition resin.

2. The substrate according to claim 1, wherein a thickness of the first base layer is larger than that of the second base layer.

3. The substrate according to claim 2, wherein the first base layer includes glass and the second base layer includes polyethylene terephthalate (PET).

4. A method for fabricating organic light-emitting diodes comprising:
providing a substrate including a first base layer, a binding layer, and a second base layer, wherein the binding layer is bound between the first base layer and the second base layer, and the binding layer includes an ultraviolet rays (UV) decomposition resin;
forming a polyimide (PI) film on the second base layer;
sequentially forming a first electrode layer, a function layer, a second electrode layer, and a package layer on the PI film;
using ultraviolet rays to irradiate the first base layer of the substrate, thereby decomposing the binding layer; and
peeling off the first base layer to form organic light-emitting diodes.

5. The method for fabricating organic light-emitting diodes according to claim 4 wherein a thickness of the first base layer is larger than that of the second base layer.

6. The method for fabricating organic light-emitting diodes according to claim 5, wherein the first base layer comprises glass, and the second base layer includes polyethylene terephthalate (PET).

7. The method for fabricating organic light-emitting diodes according to claim 6, wherein the PI film is coated on an upper surface of the second base layer.

8. The method for fabricating organic light-emitting diodes according to claim 4, wherein the binding layer is doped with a photosensitive resin.

9. The method for fabricating organic light-emitting diodes according to claim 8, wherein the binding layer includes an acrylate copolymer solution, a multi-functional group photosensitive resin, a photoinitiator, and a plasticizer.

10. The method for fabricating organic light-emitting diodes according to claim 9, wherein the multi-functional group photosensitive resin is three-group polyurethane acrylate.

11. The method for fabricating organic light-emitting diodes according to claim 5, wherein the binding layer is doped with a photosensitive resin.

12. The method for fabricating organic light-emitting diodes according to claim 11, wherein the binding layer includes an acrylate copolymer solution, a multi-functional group photosensitive resin, a photoinitiator, and a plasticizer.

13. The method for fabricating organic light-emitting diodes according to claim 12, wherein the multi-functional group photosensitive resin is three-group polyurethane acrylate.

14. The method for fabricating organic light-emitting diodes according to claim 6, wherein the binding layer is doped with a photosensitive resin.

15. The method for fabricating organic light-emitting diodes according to claim 14, wherein the binding layer includes an acrylate copolymer solution, a multi-functional group photosensitive resin, a photoinitiator, and a plasticizer.

16. The method for fabricating organic light-emitting diodes according to claim 15, wherein the multi-functional group photosensitive resin is three-group polyurethane acrylate.

17. The method for fabricating organic light-emitting diodes according to claim 7, wherein the binding layer is doped with a photosensitive resin.

18. The method for fabricating organic light-emitting diodes according to claim 17, wherein the binding layer includes an acrylate copolymer solution, a multi-functional group photosensitive resin, a photoinitiator, and a plasticizer.

19. The method for fabricating organic light-emitting diodes according to claim 18, wherein the multi-functional group photosensitive resin is three-group polyurethane acrylate.

20. A method for fabricating organic light-emitting diodes comprising:
providing a substrate comprising a first base layer, a binding layer, and a second base layer, wherein the binding layer is bound between the first base layer and the second base layer, and the binding layer includes an ultraviolet rays (UV) decomposition resin;
forming a polyimide (PI) film on the second base layer;
sequentially forming a first electrode layer, a function layer, a second electrode layer, and a package layer on the PI film;
using ultraviolet rays to irradiate the first base layer of the substrate, thereby decomposing the binding layer; and
peeling off the first base layer to form organic light-emitting diodes, wherein the binding layer comprises an acrylate copolymer solution, a multi-functional group photosensitive resin, a photoinitiator, and a plasticizer, and the acrylate copolymer solution comprises ethyl acrylate, iso-octyl acrylate, methyl methacrylate, acrylic acid.
